(19) United States
(12) Patent Application Publication
(10) Pub. No.: US 2026/0309142 A1
(43) Pub. Date: Oct. 8, 2026

(54) DIAPHRAGM PUMP

(71) Applicant: CKD CORPORATION, Komaki-shi, Aichi (JP)

(72) Inventors: Shoji AZUMA, Komaki-shi (JP); Shigenobu NISHIDA, Komaki-shi (JP); Honatsu NAKAMURA, Komaki-shi (JP)

(73) Assignee: CKD CORPORATION, Komaki-shi, Aichi (JP)

(21) Appl. No.: 19/506,076

(22) PCT Filed: Jul. 30, 2024
(86) PCT No.: PCT/JP2024/027134

§ 371 Date: Jan. 27, 2026

(30) Foreign Application Priority Data
Sep. 13, 2023 (JP) 2023-148667

(51) Int. Cl. F04B 43/067; F04B 43/00; H10P 72/00

(52) U.S. Cl. CPC F04B 43/067; F04B 43/0054; F05C 2225/08; H10P 72/0404

(57) ABSTRACT

A diaphragm pump for sucking and discharging a resist liquid supplied to a semiconductor wafer by a predetermined amount is provided with a diaphragm, a body, a detected part, and a detecting part. The diaphragm is formed by forming a film-like resin. The body has a space part in which the diaphragm is disposed so as to be displaceable, and the space part is partitioned into a chemical liquid chamber and a drive chamber. The detected part is held by the body so as to be able to come into contact with a surface positioned on the side of the drive chamber of the diaphragm, and can move following the diaphragm. The detecting part detects the displacement of the diaphragm on the basis of the position of the detected part.

### TECHNICAL FIELD

The invention relates to a diaphragm pump, which will be installed in chemical solution supply lines for semiconductor manufacturing devices.

### BACKGROUND ART

Diaphragm pumps are installed in chemical solution supply lines for semiconductor manufacturing devices and used to control supply of chemical solutions to semiconductor wafers. Each diaphragm pump accommodates therein a diaphragm in a displaceable form, which divides the space part formed inside a body of the diaphragm pump into a chemical solution chamber and a drive chamber. The internal pressure of the drive chamber is alternately changed to positive pressure and negative pressure, causing the diaphragm to be displaced toward the chemical solution chamber side and the drive chamber side alternately to discharge and suck chemical solutions. The diaphragm pump is equipped with a magnet and a magnet position sensor to detect the displacement of the diaphragm. At the center of the diaphragm on the drive chamber side, a connecting portion is provided protruding from a film portion. Further, the magnet is fixed to the connecting portion with a screw, and the magnet position sensor is installed in the body. By detecting the position of the diaphragm based on the magnet position, it is possible to control the discharge amount of the chemical solution to a predetermined amount (e.g., see Patent Document 1).

Further, in order to suppress particles generated from the surface of the diaphragm, the diaphragm of the diaphragm pump is made of PFA (polyfluoroethylene-perfluoroalkyl vinyl ether copolymer resin), and the diaphragm surface is smoothed through extrusion molding (e.g., see Patent Document 2).

### RELATED ART DOCUMENTS

### Patent Documents

Patent Document 1: Japanese unexamined patent application publication No. 2006-46284
Patent Document 2: Japanese U.S. Pat. No. 6,602,553

### SUMMARY OF INVENTION

### Problems to be Solved by the Invention

The diaphragm of the diaphragm pump repeats alternate displacement between a bulging state from a neutral position toward the drive chamber (Suction) and a bulging state from the neutral position toward the chemical solution chamber (Discharge). During displacement, the diaphragm is subjected to stress concentrated on areas around the boundary between a connecting portion and a film portion, and those areas are prone to deterioration.

Moreover, even if the diaphragm is made of a material that is less likely to generate particles, particles may still be generated from the deteriorated areas of the diaphragm due to stress concentration. In recent years, the miniaturization of semiconductor circuits has advanced to the point where even minute particles smaller than 20 nm that could not be detected by a particle measurement device may affect the yield of semiconductors. Therefore, for diaphragm pumps used in the manufacture of semiconductors, it is desirable to eliminate the causes of generating particles as much as possible and suppress the generation of particles.

### Means of Solving the Problems

To achieve the above-mentioned purpose, one aspect provides (1) a diaphragm pump for sucking and discharging a predetermined amount of a chemical solution at a time, which is to be supplied to a semiconductor wafer, the diaphragm pump comprising: a diaphragm made of resin and having a film shape; a body including a space part in which the diaphragm is placed to be displaceable, the space part being divided by the diaphragm into a chemical solution chamber in which the chemical solution flows and a drive chamber to which an operating fluid for displacing the diaphragm is supplied; a detected part held in the body to contact a surface of the diaphragm, located on a side facing the drive chamber, the detected part being movable to follow the diaphragm; and a detecting part that detects displacement of the diaphragm based on a position of the detected part.

In the diaphragm pump configured as above, the position of the diaphragm is detected based on the position of the detected part that moves to follow the diaphragm. While the detected part is moving to follow the film-shaped diaphragm, this diaphragm is only in contact with the detected part and thus can be freely deformed relative to the detected part. The diaphragm is therefore less likely to deteriorate due to stress concentration, enabling to suppress the generation of particles. Consequently, the diaphragm pump configured as above to have the function of detecting displacement of the diaphragm can enhance the durability of the diaphragm and suppress the generation of particles.

(2) In the diaphragm pump described in (1), preferably, the diaphragm is made by extrusion molding, rolling process, or both the extrusion molding and the rolling process.

In the diaphragm pump configured as above, the surface of the diaphragm is not subjected to cutting machining and thus the surface of the diaphragm is smooth without having irregularities due to machining marks. This can suppress the generation of particles caused by the surface irregularities of the diaphragm.

(3) In the diaphragm pump described in (1) or (2), preferably, the diaphragm is made of PFA.

The diaphragm pump configured as above is made of PFA as raw material and thus can suppress particles from occurring at a wetted surface in contact with a liquid, as compared with a diaphragm made of PTFE by compression molding. Therefore, the diaphragm pump using the diaphragm made of PFA as the raw material can suppress the generation of particles that affect manufacturing of semiconductors.

(4) In the diaphragm pump described in any one of (1) to (3), preferably, the detected part is movable at a moving distance shorter than a maximum stroke amount of the diaphragm.

In the diaphragm pump configured as above, the detected part moves following the diaphragm during a part of the stroke of the diaphragm, but does not follow the diaphragm during a remaining part of the stroke. This configuration can prevent the diaphragm from rubbing against a movable part, and hence improve the durability of the diaphragm.

(5) In the diaphragm pump described in any one of (1) to (4), preferably, the diaphragm has a film thickness of 0.1 mm or more and 0.3 mm or less.

In the diaphragm pump configured as above, the diaphragm has a thin thickness of 0.1 mm or more and 0.3 mm or less. Thus, the tensile force on the diaphragm during displacement is low, allowing the diaphragm to easily deform in response to the internal pressure of the drive chamber. This diaphragm pump configured as above can be expected to achieve excellent discharge performance. Further, the diaphragm with the thin film thickness is less likely to deteriorate due to stress concentration during deformation, thus suppressing the generation of particles.

(6) Preferably, the diaphragm pump described in (5) further comprises an urging member that urges the detected part toward the space part, wherein the urging member has an urging force of 0.05 N or more and 0.15 N or less.

In the diaphragm pump configured as above, the urging force of the urging member to urge the detected part toward the space part is a load that is not significantly greater than the tensile force of the thin diaphragm. This configuration enables the diaphragm to freely deform with respect to the detected part.

(7) In the diaphragm pump described in any one of (1) to (6), preferably, when the diaphragm is in an unloaded state where no load is applied to the diaphragm, a part of the diaphragm corresponding to the space part is placed in a deflected state inside the body.

In the diaphragm pump configured as above, the tensile force does not act on the diaphragm during displacement of the diaphragm. This makes it less likely to cause pressure loss during displacement of the diaphragm, resulting in stable discharge amounts of the chemical solutions. Further, in the diaphragm pump, the stress less concentrates on the diaphragm during displacement, and therefore the diaphragm is less susceptible to damage.

(8) In the diaphragm pump described in any one of (1) to (7), preferably, the body includes a retaining hole that has a bottom and opens in an inner wall of the drive chamber, the detected part and an urging member that urges the detected part toward the space part are accommodated in the retaining hole, and the detecting part is placed outside the retaining hole.

In the diaphragm pump configured as above, the detected part and the detecting part are placed while the drive chamber is hermetically sealed. This configuration can suppress leakage of an operating fluid from the detected part and prevent corrosion of the detected part due to the chemical solution permeating through the diaphragm.

(9) In the diaphragm pump described in (8), preferably, the detected part includes: a magnet to be detected by the detecting part; a movable part equipped with the magnet and accommodated in the retaining hole so that the movable part is able to protrude or retract; and a stopper part placed in the retaining hole to restrict movement of the movable part.

The diaphragm pump can be configured as above with a compact structure, in which the detected part is movably placed in an independent manner from the diaphragm within the body while suppressing the generation of the particles from the detected part.

### Effects of the Invention

According to the technique disclosed in the present description, the diaphragm pump having the function of detecting displacement of a diaphragm can enhance the durability of the diaphragm and suppress the generation of particles.

### BRIEF DESCRIPTION OF THE DRAWINGS

FIG. 1 is a cross-sectional view of a diaphragm pump in an unloaded state.

FIG. 2 is a cross-sectional view of the diaphragm pump in a discharge completion state.

FIG. 3 is a cross-sectional view of the diaphragm pump in a suction completion state.

FIG. 4 is an enlarged view of a section A1 in FIG. 1.

FIG. 5 is an enlarged view of a section A2 in FIG. 2.

FIG. 6 is an enlarged view of a detected part.

FIG. 7 is an enlarged view of a section A3 in FIG. 5.

FIG. 8 is a cross-sectional view of the diaphragm pump in a modified example.

### MODE FOR CARRYING OUT THE INVENTION

An embodiment of the invention will be described referring to the drawings. The present description shows a diaphragm pump, which is installed in a semiconductor manufacturing device and used to supply a resist solution.

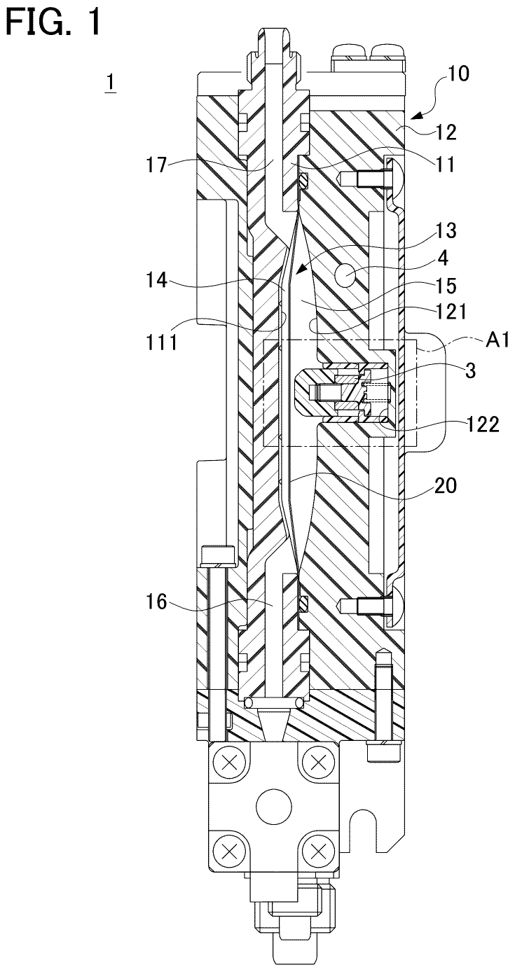

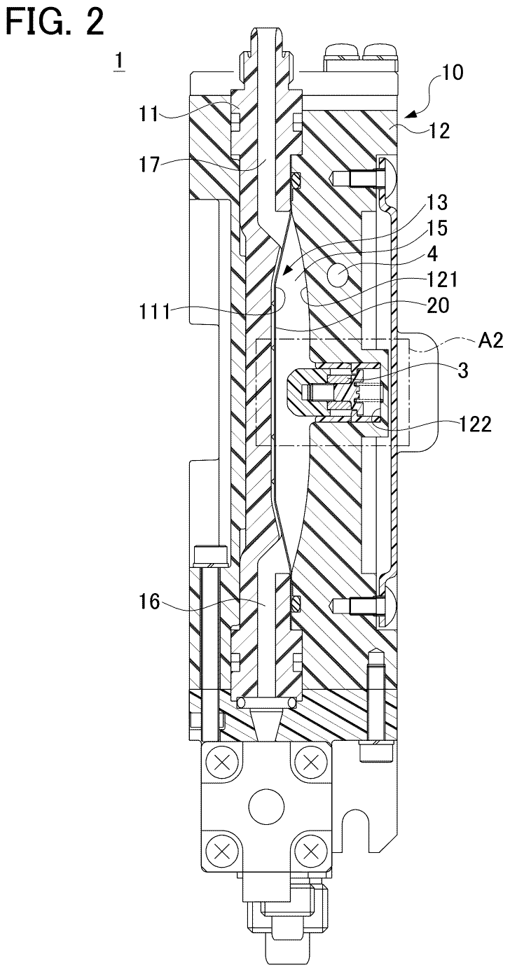

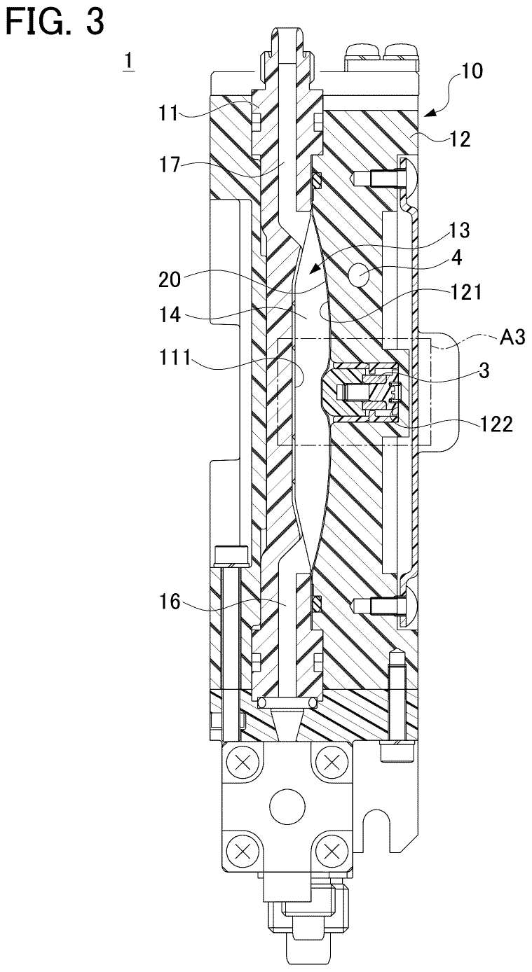

A diaphragm pump 1 shown in FIG. 1 to FIG. 3 is placed in a chemical solution supply line of the semiconductor manufacturing device and used to control the supply of a chemical solution to semiconductor wafers not illustrated. The diaphragm pump 1 controls a resist solution as one example of a chemical solution. The diaphragm pump 1 can discharge and suck a predetermined amount of the resist solution at a time by bringing a drive chamber 15 alternately into a positive pressure state and a negative pressure state, causing a diaphragm 20 shown in FIG. 1 to be displaced toward a chemical solution chamber 14 or the drive chamber 15 as shown in FIG. 2 and FIG. 3.

As shown in FIG. 1, the diaphragm pump 1 is provided with a body 10, the diaphragm 20, a part 3 to be detected (a “detected part 3”), and a part 4 for detecting (a “detecting part 4”).

The body 10 includes a first housing 11 and a second housing 12, which are connected to each other by interposing the diaphragm 20 therebetween. The first housing 11 and the second housing 12 are each made of highly corrosion-resistant fluorine resin. In the present embodiment, those first housing 11 and second housing 12 are made of PFA.

The first housing 11 and the second housing 12 have a first concave surface 111 and a second concave surface 121 respectively, as mutual contact surfaces, each having a nearly dome shape. The body 10 has a space part 13 formed between the first housing 11 and the second housing 12 and defined by the first concave surface 111 and the second concave surface 121. In the space part 13, the diaphragm 20 is flexibly placed. The diaphragm 20 has a film shape and its outer edge is clamped between the first housing 11 and the second housing 12 to hermetically divide the space part 13 into the chemical solution chamber 14 and the drive chamber 15.

The first housing 11 is formed with an inflow passage 16 and an outflow passage 17, which open in the first concave surface 111 and form a flow channel for flowing the resist solution into and out of the chemical solution chamber 14. The second housing 12 is formed with an operation flow passage not shown, which opens in the second concave surface 121 and forms a flow channel for supplying and exhausting operating air into and out of the drive chamber 15. The operating air is one example of an “operating fluid”.

The diaphragm 20 is made of resin that is easy to mold. The diaphragm 20 is preferably made of highly corrosion-resistant fluorine resin. More preferably, the diaphragm 20 is made of PFA. This is because the inventors confirmed that the diaphragm made of PFA generated fewer particles than the diaphragm made of PTFE (polytetrafluoroethylene) by testing the diaphragm pump 1 incorporating the PTF-made diaphragm 20 and another diaphragm pump incorporating the PTFE-made diaphragm through a method that supplied a fixed amount of a fluid to each of the diaphragm pumps and then counted the number of particles contained in the fixed amount of the fluid using a counter.

The raw material of the diaphragm 20 may also be other fluorine resins, such as PP (polypropylene), PVDF (polyvinylidene fluoride resin), and PVDC (polyvinylidene chloride), instead of PFA. The diaphragms made of such fluorine resins can also be expected to suppress particles more effectively than the PTFE-made diaphragm. Furthermore, the diaphragms made of those fluorine resins as the raw materials can be formed by extrusion molding, rolling process, or both, and therefore can be expected to enhance the effect of suppressing the generation of particles.

The diaphragm 20 is shaped in the form of a thin film. The film thickness of the diaphragm 20 is preferably 0.1 mm or more and 0.3 mm or less. The reason is that if the film thickness of the diaphragm 20 is less than 0.1 mm, it may tear when contacting the detected part 3. In contrast, if the film thickness of the diaphragm 20 exceeds 0.3 mm, a large tensile force acts on the diaphragm 20, which may decrease the pump discharge performance or cause the generation of particles due to stress concentration.

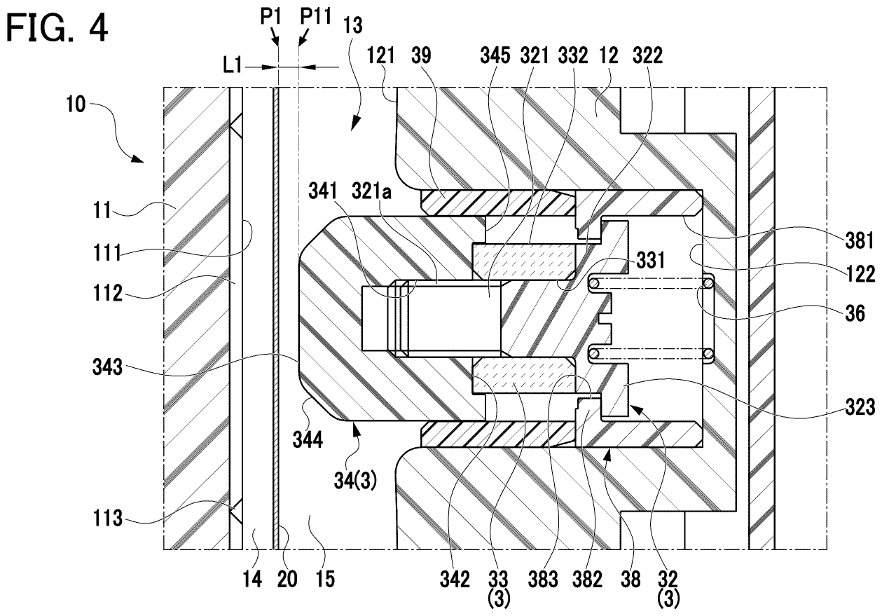

The diaphragm 20 is formed such that its portion located in the space part 13 can be deflected, or deformed, in one direction. As shown in FIG. 4, this is to ensure that when the diaphragm 20 is mounted in an unloaded state in the body 10, the detected part 3 is positioned at a predetermined distance L1 from the diaphragm 20 so that no tensile force acts on the diaphragm 20. Specifically, the diaphragm 20 shaped to be deflected toward the chemical solution chamber 14 can increase the range in which the diaphragm 20 can be displaced separately from the detected part 3, suppressing wear of the diaphragm 20. The position of the diaphragm 20 in the unloaded state is defined as a “neutral position P1”.

The diaphragm 20 in the present embodiment is shaped in such a form as shown in FIG. 1 by extrusion molding, and then its surface is smoothed by rolling process. This is to suppress the generation of particles from the surface of the diaphragm 20.

The body 10 has a retaining hole 122 formed in a cylindrical shape in the center of the second concave surface 121. The detected part 3 is provided separately from the diaphragm 20 and movably accommodated in the retaining hole 122. The detected part 3 is held by the body 10 such that the detected part 3 can contact the surface of the diaphragm 20, placed on the side facing the drive chamber 15, and can move to follow the movement of the diaphragm 20.

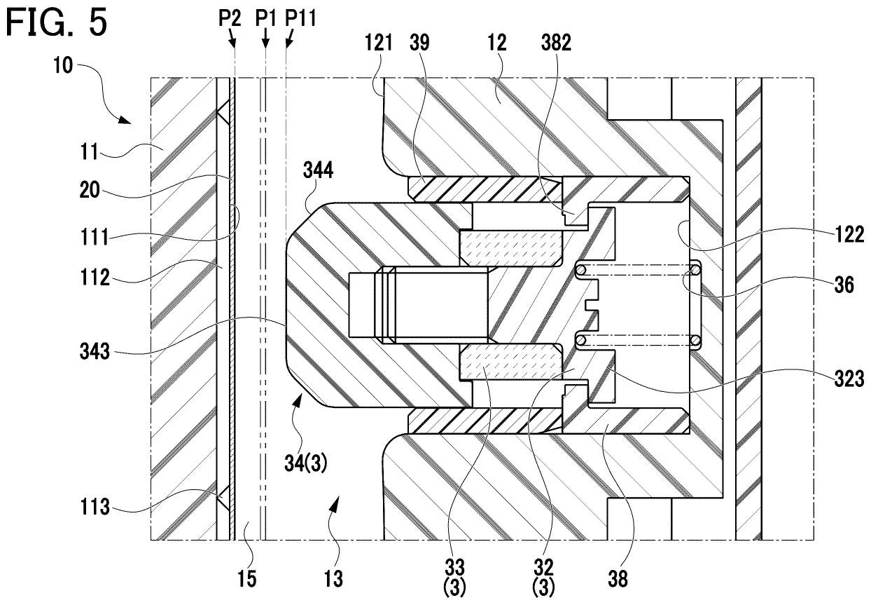

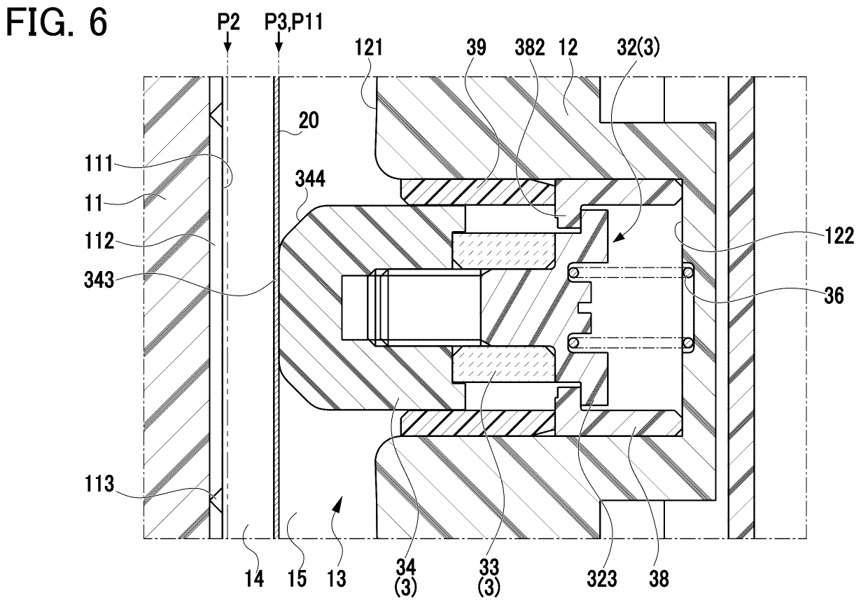

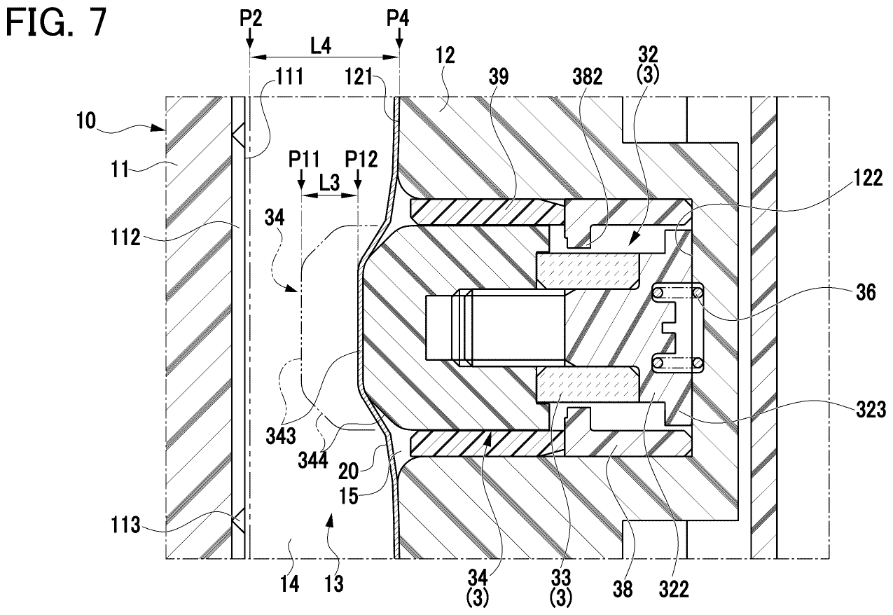

The configuration of the detected part 3 will be described specifically with reference to FIG. 4 to FIG. 7. FIG. 4 is an enlarged view of a section A1 in FIG. 1. FIG. 5 is an enlarged view of a section A2 in FIG. 2. FIG. 6 is an enlarged view similar to FIG. 4, showing that the diaphragm 20 is in contact with the detected part 3. FIG. 7 is an enlarged view of a section A3 in FIG. 3.

As shown in FIG. 4 to FIG. 7, the detected part 3 is composed of a pump screw 32, a magnet 33, and a plunger 34. The magnet 33 is held between the pump screw 32 and the plunger 34. The pump screw 32 and the plunger 34 are one example of a “movable part”.

The detected part 3 is retained in the retaining hole 122 with a guide member 38 and a bush 39 so as to be movable in the displacement direction of the diaphragm 20 (in the right and left direction in the figures). The detected part 3 is always urged in the direction to protrude from the retaining hole 122 by a spring 36.

As shown in FIG. 4, the magnet 33 has a cylindrical shape with a hollow hole 331. The pump screw 32 has a head portion 322 at one end of a leg part 321 formed with a male threaded portion 321a. The outer diameter of the head portion 322 is set to be approximately the same as the outer diameter of an outer peripheral surface 332 of the magnet 33. The plunger 34 has a nearly cylindrical shape with a surface 345 opposite the contact surface 343 which will contact the diaphragm 20. The plunger 34 is formed with a female threaded hole 341 that opens in the surface 345 and threadedly engages with the male screw portion 321a.

In the detected part 3, the leg part 321 of the pump screw 32 inserted through the hollow hole 331 of the magnet 33 is screwed into the plunger 34. The magnet 33 is held between the plunger 34 and the head portion 322 of the pump screw 32 and restricted from movement in the axial direction. The plunger 34 includes a stepped portion 342 formed annularly along the outer circumference of the opening of the female threaded hole 341. The stepped portion 342 and the leg part 321 of the pump screw 32 suppress wobbling of the magnet 33 in the radial direction.

The moving amount of the detected part 3 is restricted by the guide member 38. The guide member 38 has a cup shape with an opening portion 381 that opens on one side, and a through hole 383 formed in a closing surface 382. The guide member 38 is fitted in the retaining hole 122 so that an open end of the guide member 38 abuts against the bottom surface of the retaining hole 122.

The head portion 322 of the pump screw 32 is provided with a flange portion 323 protruding outward in the radial direction along the outer circumference of the end face located on the side opposite the leg part 321. The inner diameter of the through hole 383 is larger than the outer diameter of the head portion 322 and smaller than the outer diameter of the flange portion 323. The detected part 3 is mounted in the guide member 38 so that the flange portion 323 can be brought into contact with the closing surface 382 from the opening portion 381 side.

The spring 36 is placed in a compressed state between the head portion 322 of the pump screw 32 and the bottom surface of the retaining hole 122 to continuously apply the urging force to the detected part 3 in the direction to protrude from the retaining hole 122 into the drive chamber 15. The spring 36 is one example of an “urging member”. When the flange portion 323 is locked by the closing surface 382, the detected part 3 is restricted from moving in the protruding direction from the retaining hole 122 into the drive chamber 15. In other words, the maximum protruding amount of the detected part 3 protruding into the drive chamber 15 is specified. The position of the detected part 3 in this case is defined as an “OFF position P11”.

As shown in FIG. 7, when the flange portion 323 is locked against the bottom surface of the retaining hole 122, the detected part 3 is restricted from moving in the direction to retract from the drive chamber 15 into the retaining hole 122. In other words, the minimum protruding amount of the detected part 3 protruding into the drive chamber 15 is specified. The position of the detected part 3 in this case is defined as an “ON position P12”. In the present embodiment, the flange portion 323, the closing surface 382, and the bottom surface of the retaining hole 122 constitute one example of a “stopper part”.

In the detected part 3, the contact surface 343 of the plunger 34 that contacts the diaphragm 20 is provided flat, and a corner 344 of the contact surface 343 is subjected to R-processing (rounding) into a smooth curved face. This reduces friction resistance which may occur between the detected part 3 and the diaphragm 20.

The moving distance L3 of the detected part 3 moving from the OFF position P11 to the ON position P12 is set shorter than the maximum stroke amount L4 of the diaphragm 20. This maximum stroke amount L4 is the distance between a discharge completion position P2, where the diaphragm 20 deforms along the first concave surface 111, and a full stroke position P4, where the diaphragm 20 deforms along the second concave surface 121. This is to ensure that the detected part 3 contacts the diaphragm 20 during part of the stroke of the diaphragm 20 as shown in FIG. 6 and FIG. 7, and does not contact the diaphragm 20 during remaining part of the stroke of the diaphragm 20 as shown in FIG. 4 to FIG. 6. This reduces the range where the diaphragm 20 contacts the detected part 3, thereby suppressing wear of the diaphragm 20.

The moving distance L3 is preferably 50% or less of the maximum stroke amount L4. This is to reduce the displacement range of the diaphragm 20 in a contact state with the detected part 3, thereby suppressing wear of the diaphragm 20. More preferably, the moving distance L3 is 30% or less of the maximum stroke amount L4. This is because when the diaphragm 20 comes into contact with the detected part 3 just before reaching the full stroke position P4, the load applied to the diaphragm 20 from the detected part 3 is reduced, and thus the durability of the diaphragm 20 is improved.

The diaphragm pump 1 discharges and sucks the resist solution by switching the drive chamber 15 between the positive pressure state and the negative pressure state. Thus, the spring 36 is placed in order to return the detected part 3 from the ON position P12 to the OFF position P11, not to displace the diaphragm 20. Consequently, the urging force of the spring 36 is set to apply a load to the diaphragm 20 to the extent that the load does not significantly exceed the tensile force of the diaphragm 20. Since the diaphragm 20 in the present embodiment has a thin film thickness of 0.1 mm or more and 0.3 mm or less and has a small tensile force, the urging force of the spring 36 is set to be 0.05 N or more and 0.15 N or less.

The bush 39 is press-fitted in the retaining hole 122 until the bush 39 comes into contact with the guide member 38 to retain the guide member 38 in position within the retaining hole 122 under the urging force exerted by the spring 36. Since the guide member 38 and the bush 39 are press-fitted in the retaining hole 122, the detected part 3 can be mounted in the retaining hole 122 without causing twisting of the spring 36. The bush 39 is placed between the inner peripheral surface of the retaining hole 122 and the outer peripheral surface of the plunger 34 to hold the plunger 34 slidably.

The pump screw 32, the plunger 34, the guide member 38, and the bush 39 are each made of fluorine resin. These components are preferably produced using processing methods, such as extrusion molding and injection molding, other than cutting machining. This is to suppress the generation of particles from machining marks and enable the detected part 3 to move with high responsivity to follow the displacement of the diaphragm 20.

Returning to FIG. 1, the detecting part 4 is a magnetic sensor for detecting the position of the detected part 3. The detecting part 4 is placed outside the retaining hole 122 and detects the displacement of the diaphragm 20 based on the position of the detected part 3. The detecting part 4 is connected to a high-order controller that manages processes for semiconductor wafers not shown. When the detected part 3 is disposed in the ON position P12, the detecting part 4 transmits a detection signal to the high-order controller not shown. When the detected part 3 is not disposed in the ON position P12, the detecting part 4 does not send a detection signal to the high-order controller not shown.

Next, the operations of the diaphragm pump 1 will be described. When the drive chamber 15 of the diaphragm pump 1 shown in FIG. 1 becomes under positive pressure by operating air supplied thereto, the diaphragm 20 deforms along the first concave surface 111 and is disposed at the discharge completion position P2. This operation minimizes the volume of the chemical solution chamber 14.

As shown in FIG. 5, when the diaphragm 20 is disposed at the discharge completion position P2, the detected part 3 is placed at the OFF position P11 where the flange portion 323 of the pump screw 32 is locked by the closing surface 382 of the guide member 38.

The diaphragm 20 is disposed at the discharge completion position P2 separately from the detected part 3 disposed at the OFF position P11. In addition, the diaphragm 20 is assembled to the body 10 so that the diaphragm 20 is deflected toward the first concave surface 111 in the unloaded state. Thus, the diaphragm 20 has a smaller tensile force at the discharge completion position P2 than a diaphragm assembled in a flat state to the body 10 in the unloaded state.

The detecting part 4 shown in FIG. 2 does not detect the magnet 33 of the detected part 3 when the detected part 3 is at the OFF position P11. Accordingly, the detecting part 4 does not send a detection signal to the high-order controller not shown.

When the operating air is exhausted from the drive chamber 15 of the diaphragm pump 1 shown in FIG. 2, decreasing the internal pressure of the drive chamber 15, the diaphragm 20 deforms toward the second concave surface 121 (toward the drive chamber 15) by its own elastic force, reducing the sealing strength of the diaphragm 20 that tightly contacts the first concave surface 111.

As shown in FIG. 5, the first concave surface 111 has a plurality of grooves 112 formed in a circumferential direction and further a plurality of grooves 113 formed in a radial direction. Accordingly, when the sealing strength decreases, the resist solution having entered in the inflow passage 16 begins to pass through the grooves 112 and 113 toward the outflow passage 17. This applies the force on the diaphragm 20 in a direction to separate away from the first concave surface 111 (toward the second concave surface 121).

Thus, when the operating air begins to be exhausted from the drive chamber 15 of the diaphragm pump 1, the diaphragm 20 is separated from the first concave surface 111 with high responsivity and displaced toward the second concave surface 121 (toward the drive chamber 15) by its own elastic force and the pressure of the resist solution.

From the discharge completion position P2 to the contact position P3 where the diaphragm 20 comes into contact with the contact surface 343 of the detected part 3, the diaphragm 20 is displaced while remaining separated from the detected part 3, as shown in FIG. 6. Thus, during displacement of the diaphragm 20 from the discharge completion position P2 to the contact position P3, the detected part 3 remains located at the OFF position P11 without following the movement of the diaphragm 20.

When the diaphragm 20 deforms so as to bulge from the contact position P3 toward the second concave surface 121, the diaphragm 20 presses against the contact surface 343 of the detected part 3 toward the retaining hole 122. The urging force of the spring 36, biasing the detected part 3, is small, ranging from 0.05 N to 0.15 N. Therefore, the detected part 3 can move in the retracting direction in accordance with the diaphragm 20 without disturbing the displacement of the diaphragm 20.

In the diaphragm pump 1, the diaphragm 20 is displaced to the full stroke position P4 where the diaphragm 20 deforms along the second concave surface 121, as shown in FIG. 3. As the diaphragm 20 deforms to bulge toward the second concave surface 121, the resist solution flows into the chemical solution chamber 14. When the diaphragm 20 is displaced to the full stroke position P4, the volume of the chemical solution chamber 14 becomes maximum.

The detected part 3 is disposed at the ON position P12 as shown in FIG. 7, where the head portion 322 of the pump screw 32 touches the bottom surface of the retaining hole 122, restricting the detected part 3 from further moving in the retracting direction. At that time, the plunger 34 of the detected part 3 slightly protrudes toward the drive chamber 15. Thus, the detected part 3 is pushed into the retaining hole 122 by the diaphragm 20 placed at the full stroke position P4, and is stably positioned at the ON position P12.

In the detected part 3, the contact surface 343 is flat, and the corner 344 of the contact surface 343 is a smooth curved surface. Accordingly, the diaphragm 20 placed at the full stroke position P4 is gently deformed between the contact surface 343 and the second concave surface 121, making it less prone to deterioration due to stress concentration at a portion of the diaphragm 20 contacting the detected part 3. It is consequently possible to suppress the generation of particles from a deteriorated portion by stress concentration.

When the detected part 3 is placed at the ON position P12, the detecting part 4 shown in FIG. 3 detects the magnet 33 and sends a detection signal to the high-order controller not shown. Based on this detection signal, the high-order controller not shown detects that the diaphragm pump 1 has sucked a predetermined amount of When the drive chamber 15 of the diaphragm pump 1 shown in FIG. 3 is supplied with operating air and comes to the positive pressure state, the diaphragm 20 is displaced to the discharge completion position P2 as shown in FIG. 2. As the diaphragm 20 is shaped to bulge toward the first concave surface 111, the resist solution flowing into the chemical solution chamber 14 in a predetermined amount is discharged through the outflow passage 17.

When the diaphragm 20 begins to be displaced toward the first concave surface 111 (toward the chemical solution chamber 14 side), the detected part 3 is urged to move in the protruding direction by the spring 36, as shown in FIG. 6. Specifically, the detected part 3 can move to follow the diaphragm 20.

The detected part 3 and the diaphragm 20 are separate components, and the detected part 3 simply contacts the diaphragm 20. Thus, when the detected part 3 moves to follow the diaphragm 20, the diaphragm 20 can freely deform relative to the detected part 3, and the tensile force acting on the portion of the diaphragm 20 contacting the detected part 3 is small.

Moreover, the urging force of the spring 36 is as small as 0.05 N or more and 0.15 N or less. This results in a small load acting on the portion of the diaphragm 20 contacting the detected part 3. Consequently, even when the detected part 3 comes into contact with the diaphragm 20 and moves to follow the diaphragm 20, the diaphragm 20 is less likely to wear at the portion contacting the detected part 3 and therefore is unlikely to generate particles.

As shown in FIG. 5, the detected part 3 is not allowed to move in the protruding direction beyond the OFF position P11 because the flange portion 323 of the pump screw 32 is locked by the closing surface 382 of the guide member 38. During displacement from the contact position P3 to the discharge completion position P2, therefore, the diaphragm 20 is displaced independently of the detected part 3. Thus, the diaphragm 20 does not receive any load other than the operating air and hence is less likely to deteriorate due to stress concentration.

When the detected part 3 is moved from the ON position P12 to the OFF position P11, the detecting part 4 shown in FIG. 2 can no longer detect the magnet 33, and therefore stops sending a detection signal to the high-order controller not shown. When the detection signal is no longer received, the high-order controller not shown detects that the diaphragm pump 1 has supplied a predetermined amount of the resist solution to semiconductor wafers not shown.

In the diaphragm pump 1, the discharge completion position P2 and the full stroke position P4 of the diaphragm 20 are defined respectively by the first concave surface 111 and the second concave surface 121, so that the maximum volume and the minimum volume of the chemical solution chamber 14 are stable. Accordingly, the diaphragm pump 1 can accurately supply a predetermined amount of the resist solution to semiconductor wafers not shown even when repeating discharge and suction.

The diaphragm 20 is installed in the body 10 with a portion of the diaphragm 20 corresponding to the space part 13 deflected toward the first concave surface 111 in the unloaded state. Therefore, no tensile force acts on the diaphragm 20 during displacement. Consequently, the diaphragm pump 1 is less likely to cause pressure loss during displacement of the diaphragm 20, resulting in stable discharge amounts of resist solution.

Since the diaphragm 20 has a thin thickness and the tensile force acting on the diaphragm 20 is small, the diaphragm 20 is easy to deform in response to pressure fluctuations in the drive chamber 15. Thus, the diaphragm pump 1 can be expected to exhibit excellent discharge performance. Further, the diaphragm 20 is less prone to deterioration due to stress concentration even after repeating deformation, and hence can suppress the generation of particles.

The diaphragm 20 is made of PFA, which is a material unlikely to generate particles. The diaphragm 20 is formed by extrusion molding and rolling process and thus has no irregularities caused by machining marks, making it less likely to generate particles. Therefore, the diaphragm 20 is less likely to generate particles from its surface even after repeated deformation.

Moreover, the diaphragm 20 is provided as a separate component from the detected part 3 and can be displaced independently of the detected part 3, so that no load other than the operating air acts on the diaphragm 20. Therefore, only small tensile force acts on the diaphragm 20, making it less likely to deteriorate the diaphragm 20 and cause particles from a deteriorated portion.

In the diaphragm pump 1, the detected part 3 moves while remaining in contact with the diaphragm 20 during part of the stroke of the diaphragm 20, as shown in FIG. 5 to FIG. 7. In this diaphragm pump 1, therefore, the diaphragm 20 is less likely to wear due to rubbing against the detected part 3, and can achieve enhanced durability, as compared with the configuration that a detected part remains in contact with the diaphragm throughout the entire stroke of the diaphragm.

Since the detected part 3 is placed on the drive chamber 15 side, even if the diaphragm 20 rubs against the detected part 3, generating particles, those particles are confined within the drive chamber 15 and therefore will not mix in the resist solution.

The diaphragm pump 1 is configured such that the detected part 3 is placed in the retaining hole 122 and the detecting part 4 that detects the detected part 3 is provided outside the retaining hole 122. That is, in the diaphragm pump 1, the detected part 3 and the detecting part 4 are placed while the drive chamber 15 is hermetically sealed. This configuration can suppress leakage of the operating air from the detected part 3, and prevent corrosion of the detecting part 4 due to the resist solution permeating through the diaphragm 20.

In the diaphragm pump 1, the detected part 3 is slidably placed in the retaining hole 122, and the movable range of the detected part 3 is restricted by making the flange portion 323 of the pump screw 32 contact with the closing surface 382 of the guide member 38 and the bottom surface of the retaining hole 122. This can suppress the generation of particles from the detected part 3. Furthermore, the diaphragm pump 1 can have a compact structure in which the detected part 3 is movably placed in the body 10 in an independent manner from the diaphragm 20.

As described above, in the diaphragm pump 1 in the present embodiment, the position of the diaphragm 20 is detected based on the position of the detected part 3 moving to follow the diaphragm 20. Since the film-shaped diaphragm 20 is only in contact with the detected part 3 while the detected part 3 is following the diaphragm 20, the diaphragm 20 can freely deform relative to the detected part 3. Therefore, the diaphragm 20 is less likely to deteriorate due to stress concentration, and suppresses the generation of particles. According to the diaphragm pump 1 in the present embodiment, consequently, the diaphragm pump 1 having the function of detecting the displacement of the diaphragm 20 can enhance the durability of the diaphragm 20 and suppress the generation of particles.

The invention is not limited to the foregoing embodiments and may be embodied in other specific forms. For example, the contact surface 343 of the detected part 3 may also be a gentle convex surface or a gentle concave surface instead of the flat surface.

For example, the diaphragm 20 may be produced by extrusion molding or rolling process. As another alternative, the diaphragm 20 may also be produced by injection molding. Furthermore, the diaphragm 20 may be formed in a manner that a resin, which is melted and plasticized in an extruder, is extruded into a thin tube shape through a tube forming die, and then this thin tube-shaped extruded product is cut open into a sheet.

For example, the film thickness of the diaphragm 20 needs not be 0.1 mm or more and 0.3 mm or less. However, the thin diaphragm 20 having a thickness ranging 0.1 mm to 0.3 mm can be expected to enhance the effect of suppressing the generation of particles when the diaphragm 20 is produced by extrusion molding or rolling process, or both.

If the diaphragm 20 and the detected part 3 are separatable independent components, the moving distance L3 of the detected part 3 may be set to be equal to the maximum stroke amount L4 of the diaphragm 20. However, the configuration that the moving distance L3 is smaller than the maximum stroke amount L4 allows the diaphragm 20 to move in a separated state from the detected part 3, and suppresses the diaphragm 20 from rubbing against the detected part 3 and wearing.

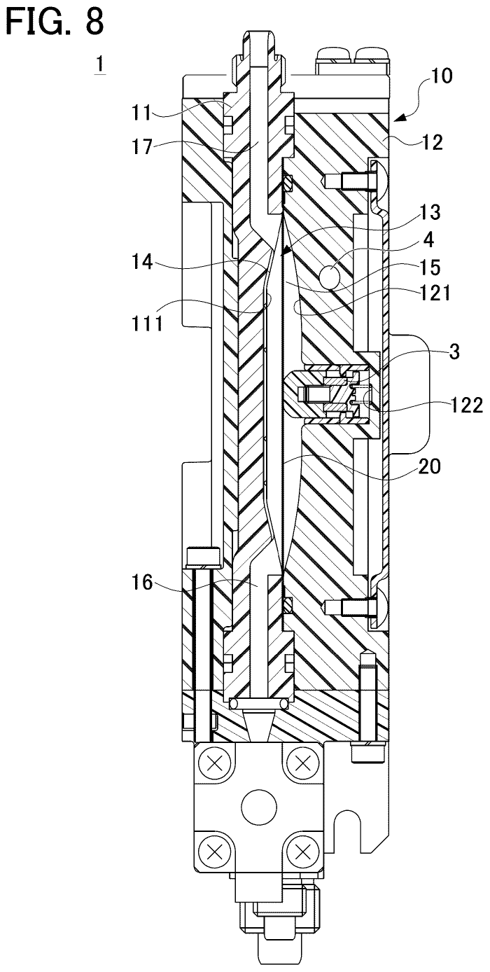

For example, as shown in FIG. 8, the diaphragm 20 may be placed in a flat state within the space part 13 when the diaphragm 20 is in the unloaded state where no load is applied thereto.

For example, the diaphragm 20 may be formed in a flat sheet shape. However, when a portion of the diaphragm 20, placed in the space part 13, is shaped to curve, the diaphragm 20 with the deflected portion corresponding to the space part 13 in the unloaded state is easily mounted in the body 10.

For example, the detecting part 4 may also be placed so as to communicate with the retaining hole 122.

For example, the pump screw 32 may be formed of separate parts; a first part engageable with the guide member 38 and a second part including the male screw portion 321a to be tightened into the female threaded hole 341 of the plunger 34.

For example, the movable part may be formed as a single component, and the magnet 33 may be assembled to the movable part by insert molding.

### REFERENCE SIGNS LIST

1 Diaphragm pump
3 Detected part
4 Detecting part
10 Body
20 Diaphragm

1. A diaphragm pump for sucking and discharging a predetermined amount of a chemical solution at a time, which is to be supplied to a semiconductor wafer, the diaphragm pump comprising:
a diaphragm made of resin and having a film shape;
a body including a space part in which the diaphragm is placed to be displaceable, the space part being divided by the diaphragm into a chemical solution chamber in which the chemical solution flows and a drive chamber to which an operating fluid for displacing the diaphragm is supplied;
a detected part held in the body to contact a surface of the diaphragm, located on a side facing the drive chamber, the detected part being movable to follow the diaphragm; and
a detecting part that detects displacement of the diaphragm based on a position of the detected part, and
wherein the detected part is movable at a moving distance shorter than a maximum stroke amount of the diaphragm.

2. The diaphragm pump according to claim 1, wherein the diaphragm is made by extrusion molding, rolling process, or both the extrusion molding and the rolling process.

3. The diaphragm pump according to claim 1, wherein the diaphragm is made of PFA.

4. (canceled)

5. The diaphragm pump according to claim 1, wherein the diaphragm has a film thickness of 0.1 mm or more and 0.3 mm or less.

6. A diaphragm pump for sucking and discharging a predetermined amount of a chemical solution at a time, which is to be supplied to a semiconductor wafer the diaphragm pump comprising:
a diaphragm made of resin and having a film shape;
a body including a space part in which the diaphragm is placed to be displaceable, the space part being divided by the diaphragm into a chemical solution chamber in which the chemical solution flows and a drive chamber to which an operating fluid for displacing the diaphragm is supplied;
a detected part held in the body to contact a surface of the diaphragm, located on a side facing the drive chamber the detected part being movable to follow the diaphragm;
a detecting part that detects displacement of the diaphragm based on a position of the detected part, and
an urging member that urges the detected part toward the space part,
wherein the diaphragm has a film thickness of 0.1 mm or more and 0.3 mm or less, and
wherein the urging member has an urging force of 0.05 N or more and 0.15 N or less.

7. A diaphragm pump for sucking and discharging a predetermined amount of a chemical solution at a time, which is to be supplied to a semiconductor wafer, the diaphragm pump comprising a diaphragm made of resin and having a film shape;
a body including a space part in which the diaphragm is placed to be displaceable the space part being divided by the diaphragm into a chemical solution chamber in which the chemical solution flows and a drive chamber to which an operating fluid for displacing the diaphragm is supplied;
a detected part held in the body to contact a surface of the diaphragm, located on a side facing the drive chamber the detected part being movable to follow the diaphragm; and
a detecting part that detects displacement of the diaphragm based on a position of the detected part,
wherein when the diaphragm is in an unloaded state where no load is applied to the diaphragm, a part of the diaphragm corresponding to the space part is placed in a deflected state inside the body.

8. A diaphragm pump for sucking and discharging a predetermined amount of a chemical solution at a time, which is to be supplied to a semiconductor wafer, the diaphragm pump comprising:
a diaphragm made of resin and having a film shape;
a body including a space part in which the diaphragm is placed to be displaceable, the space part being divided by the diaphragm into a chemical solution chamber in which the chemical solution flows and a drive chamber to which an operating fluid for displacing the diaphragm is supplied;
a detected part held in the body to contact a surface of the diaphragm, located on a side facing the drive chamber, the detected part being movable to follow the diaphragm; and
a detecting part that detects displacement of the diaphragm based on a position of the detected part,
wherein the body includes a retaining hole that has a bottom and opens in an inner wall of the drive chamber,
the detected part and an urging member that urges the detected part toward the space part are accommodated in the retaining hole, and
the detecting part is placed outside the retaining hole.

9. The diaphragm pump according to claim 8, wherein the detected part includes:
a magnet to be detected by the detecting part;
a movable part equipped with the magnet and accommodated in the retaining hole so that the movable part is able to protrude or retract; and
a stopper part placed in the retaining hole to restrict movement of the movable part.

10. The diaphragm pump according to claim 2, wherein the diaphragm is made of PFA.

11. The diaphragm pump according to claim 2, wherein the diaphragm has a film thickness of 0.1 mm or more and 0.3 mm or less.
